(19) United States
(12) Patent Application Publication
(10) Pub. No.: US 2022/0308090 A1
(43) Pub. Date: Sep. 29, 2022

(54) TEST AND MEASUREMENT INSTRUMENT HAVING PROGRAMMABLE ACQUISITION HISTORY

(71) Applicant: Tektronix, Inc., Beaverton, OR (US)

(72) Inventor: Gary J. Waldo, Hillsboro, OR (US)

(73) Assignee: Tektronix, Inc., Beaverton, OR (US)

(21) Appl. No.: 17/701,658

(22) Filed: Mar. 22, 2022

Related U.S. Application Data
(60) Provisional application No. 63/165,699, filed on Mar. 24, 2021.

(51) Int. Cl. G01R 13/02

(52) U.S. Cl. CPC G01R 13/0254

(57) ABSTRACT

A test and measurement instrument includes an input configured to receive a signal for testing, an acquisition processor configured to generate an acquisition from the received signal and store the acquisition in an acquisition memory, and copy the acquisition to a data store, and an acquisition evaluator configured to compare the selected acquisition in the data store against one or more criteria, and identify whether the acquisition meets the one or more criteria. When the acquisition meets the one or more criteria, the acquisition may be stored in a secondary memory of the instrument as a curated or selected history of measurements, on which measurements or other analysis may be made.

### PRIORITY

This disclosure claims benefit of U.S. Provisional Application No. 63/165,699, titled “Acquisition History Mode in a Test and Measurement Instrument”, filed on Mar. 24, 2021, which is incorporated herein by reference in its entirety.

### TECHNICAL FIELD

This disclosure relates to test and measurement instruments, and more particularly to technology for storing and analyzing certain data acquired by such test and measurement instruments.

### BACKGROUND

Test and measurement equipment, such as digital oscilloscopes, logic analyzers, spectrum analyzers, etc., receive a signal of interest from a device under test (DUT) and produce a visual or data measurement output in response. Most instruments also store a record of the input signal. Since the amount of memory in an instrument is finite, there is a limit to how many records, samples, or acquisitions may be stored in the instrument. The number of acquisitions capable of being stored in the instrument depends on the data sample rate, sample resolution, acquisition record length, and total amount of memory in the instrument for storing acquisitions.

An optional history mode, available on some instruments, allows a user to perform measurements on the acquisitions, or waveform samples, that are stored in the memory of the instrument, rather than measuring the test signal as it comes in from the tested device. When history mode is enabled, the user may navigate from one stored acquisition to a previous or subsequent acquisition. As the user navigates from one acquisition to another, all active analysis features of the instrument such as measurements, searches, bus decodes, etc. are run on the selected acquisition. This conventional history mode helps the user debug issues spotted in the input signal because he or she can stop and review events of interest. And because the data is stored in the instrument, the user can review the events of interest as many times as desired.

Although the history mode is helpful in debugging or examining stored input waveforms, the finite amount of memory limits the usefulness, because events that occur very infrequently are likely to not be captured by the instrument. For example, if an event occurs in the DUT an average of once every four hours, and the instrument has one hour of equivalent memory storage, then there is only a one in four chance that the event will be stored in any given one hour sample.

Examples of the disclosure address these and other deficiencies of the prior art.

### BRIEF DESCRIPTION OF THE DRAWINGS

Aspects, features and advantages of examples of the present disclosure will become apparent from the following description of examples in reference to the appended drawings in which:

FIG. 1 is a block diagram of a test and measurement instrument having a programmable history processor, according to examples of the disclosure.

FIG. 2 is a block diagram illustrating various memory stores and operations that may be applied to data stored in such memory stores, according to embodiments of the invention.

FIG. 3 is block diagram illustrating how measurements or analysis may be selectively performed on acquisitions from a main host memory or from a data store history, or both, according to embodiments of the invention.

FIG. 4 is block diagram illustrating another example of how measurements or analysis may be selectively performed on acquisitions from a main host memory, from a data store history, or from further qualified acquisitions from the data store history, according to embodiments of the invention.

FIG. 5 is a block diagram illustrating criteria that a user may invoke when configuring the programmable history processor of FIG. 1, according to embodiments of the invention.

### DESCRIPTION

Disclosed herein is a test and measurement instrument having a programmable or configurable acquisition history processor. The configurable history processor evaluates an acquisition stored in a data store of the instrument against various criteria, which are typically specified by the user. When the stored acquisition satisfies the present criteria, it is moved to a data store history, where it can be later selected, analyzed, measured, and evaluated. As described below, embodiments of the invention allows the instrument to collect multiple samples of acquisitions or events that are of high interest to the user, no matter how infrequently the events may occur during testing.

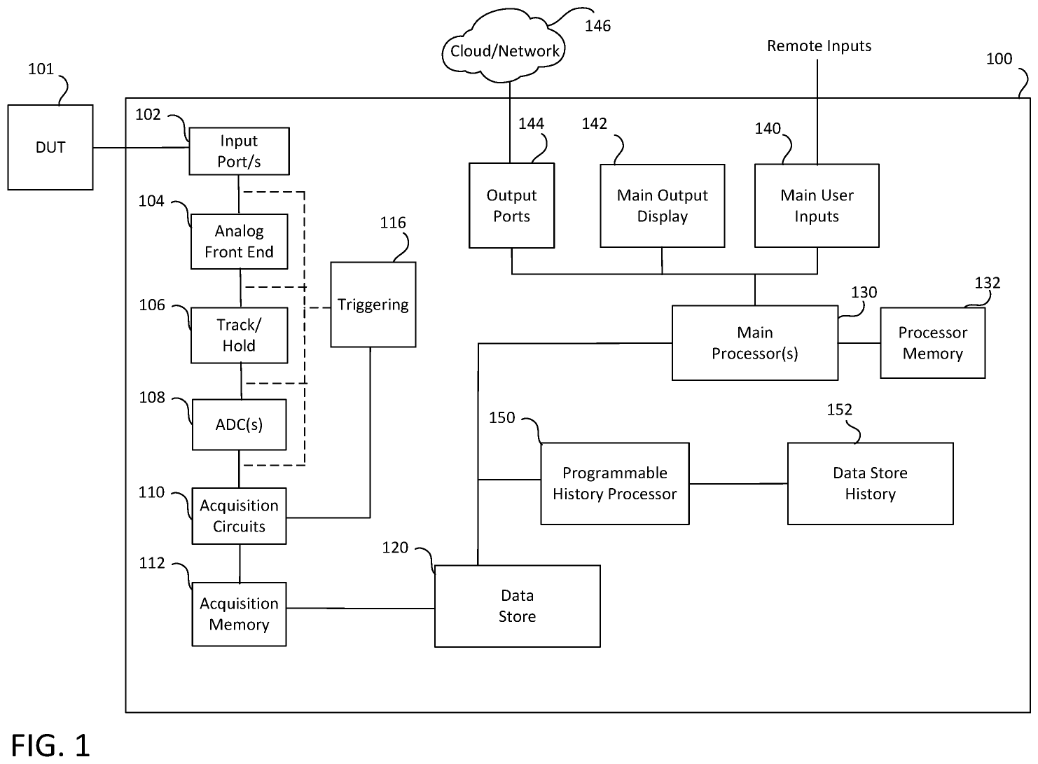

FIG. 1 is an example block diagram of a test and measurement instrument 100 including a user-configurable history processor, as described in detail below. As understood by one skilled in the art, the measurement instrument 100 may include additional components not shown in FIG. 1, or the various components and functions described herein may be combined into fewer number or split into multiple components or functions. Not all functions or components described herein need be present in all embodiments of the invention.

The instrument 100 of FIG. 1 includes one or more ports 102 which may be any electrical or optical signaling medium. Ports 102 may include receivers and/or transceivers. Each port 102 is a channel of the test and measurement instrument 100. In some embodiments the test and measurement instrument 100 includes 8, 16, or more separate ports. The test and measurement instrument 100 may couple to a Device Under Test (DUT) 101 through one or more ports 102, and receive a signal from the DUT for testing and/or measuring.

The instrument 100 may include an analog front end 104 to receive one or more analog signals from one or more devices, at least one of which is the DUT 101. The analog signals are received at a track-and-hold circuit 106, which tracks the one or more analog signals and holds samples of the one or more analog signals in response to a sample clock (not shown). The held samples of the track-and-hold circuit 106 are sent to one or more analog-to-digital converters (ADCs) 108, which converts the analog input samples to digital or digitized samples. If the input signal from the DUT 101 is already in digital form, the components 104, 106, and 108 may be bypassed. In any event, the digital samples are sent to one or more acquisition circuits 110, which acquire samples and store them in an acquisition memory 112.

The acquisition memory 112 may be a relatively large, solid state memory that is structured to store large amounts of incoming data. The acquisition memory 112 may be configured as a circular buffer that overwrites the oldest stored data as new data is stored. In some embodiments the acquisition memory 112 is configured as two circular buffers, of equal size, where a first circular buffer is storing data from the acquisition circuits 110 while a second circular buffer is sending its data to a host memory or data store 120. Then, after the second circular buffer has offloaded its data to the data store 120, the second circular buffer acquires new data from the acquisition circuit 110 while the first circular buffer offloads its data to the data store 120. In other configurations, where a memory configured as a circular buffer can be written to and read from at the same time, only a single circular buffer is used as the acquisition memory 112.

One or more trigger circuits 116 may be used to limit acquisitions to only those having certain properties selected by the user. Common triggers include edge triggers, glitch triggers, pulse-width triggers, amplitude triggers etc. Triggers may be based from a single event, or A-B triggers may be used to specify complex triggers from a combination of events. In operation, the trigger circuits 116 apply trigger criteria to the input signal, and cause the acquisition circuit 110 to store the acquisition only when the triggering condition is met. Sometimes the trigger circuits 116 receive time-based or other control signals that are separate from the input signal itself. When triggered, the trigger circuits 116 cause the acquisition circuits 110 to store a configurable amount of signal information from before the trigger occurred and a configurable amount of signal information after the trigger event. The amount of information stored based on a triggering event is referred to herein as a record or an acquisition. When the triggering circuits 116 are turned off, acquisitions may be automatically acquired from the DUT 101 at periodic intervals.

As described above, after being acquired, the acquisition from the acquisition memory 112 is automatically moved to the data store 120, which is a memory for storing the most recent acquisition in the instrument 100.

Embodiments of the invention below are described as single acquisitions. In other words, a trigger generates a single acquisition, which is then moved from the acquisition memory 112 to the data store 120 and evaluated there. Other embodiments may acquire or accumulate multiple acquisitions in the data store 120, which are later evaluated, in series, but the evaluation process is the same no matter whether it is a single or multiple acquisitions stored in the data store 120.

One or more main processors 130 are configured to execute instructions from a processor memory 132 and may perform any methods, operations, and/or associated steps indicated by such instructions, such as controlling the overall operation of the instrument 100. The one or more processors 130 may perform further processing on the acquisition stored in the data store 120 such as decoding, searching, measuring, etc, while the acquisition memory 112 is filling with the next acquisition. When the next acquisition is complete, it is automatically moved from the acquisition memory 112 to the data store 120, typically overwriting the previous acquisition.

Main user inputs 140 are coupled to the one or more processors 130. Main user inputs 140 may include a keyboard, mouse, touchscreen, programmable interface and/or any other controls employable by a user to interact with the instrument 100. User inputs may originate from outside the instrument, such as through a programmatic interface or connected Personal Computer. The instrument may include a main output display 142, which may be a Graphical User Interface (GUI). The display 142 may be a digital screen such as an LCD, or any other monitor to display waveforms, measurements, and other data to a user. In some embodiments the main output display 142 is a touchscreen, and may also receive user inputs. In some embodiments the main output display 142 is located remote from or may be duplicated at a location remote from the instrument 100. In some embodiments a remote computer may connect to the instrument 100 and cause the main display 142 to be shown on the display of the remote computer.

Output ports 144 may be used to send measurement results, measurement data, or any of the data in the instrument 100 outside of the instrument. In some embodiments the output ports 144 store data to the cloud or connected networks, such as the internet 146 or private network, such as a Local Area Network (LAN).

The instrument 100 includes a programmable history processor 150, which is described in detail below. In general, the history processor 120 uses one or more criteria to compare against the acquisition stored in the data store 120. If the acquisition stored in the data store 120 matches the one or more criteria, then the acquisition is copied or moved to a data store history 152, which is another memory. All matching acquisitions remain in the data store history 152 until specifically removed by a user, or until the data store history 152 is cleared by a user. In some embodiments the data store history 152 is a particular section or extension of the data store 120, except that data in the data store history 152 is not overwritten without specific action by a user.

Any of the memories of the instrument 100 may be implemented by any data-storing device. For instance, the acquisition memory 112 may be formed of RAM, or other type of memory. Other memory within the test and measurement instrument 100 such as the data store 120, data store history 152 and processor memory 132 may be implemented as processor cache, random access memory (RAM), read only memory (ROM), solid state memory, hard disk drive(s), or any other memory type. The data store 120, data store history 152, and processor memory 132 are generally referred to as a “host” memory, and such host memory is typically separate, physically and logically, from the acquisition memory 112. The acquisition memory 112 is typically required to be able to perform high speed writing of data to keep up with the high sample rates of the ADCs 108, and therefore acquisition memory is typically higher cost than host memory of the same size. Structuring the history processor 150 to evaluate the acquisition stored in the host memory data store 120, rather than evaluate the acquisition directly in the acquisition memory 112 itself, allows the instrument 100 to use a smaller size acquisition memory 112, and therefore have a lower cost.

The history processor 150 may accept user input from any of the methods described above with reference to main user inputs 140. For example, the user may use a menu or touchscreen to enter selection criteria to the history processor 150, or the criteria could be received through a programmatic interface. Further, the history processor 150 may output results or data through the output ports 144 as described above. In some embodiments the data store history 152 may be located in a separate device than on the instrument 100 itself, or acquisitions matching the present criteria may be sent to the internal data store history 152 and to the output port 144 at the same time.

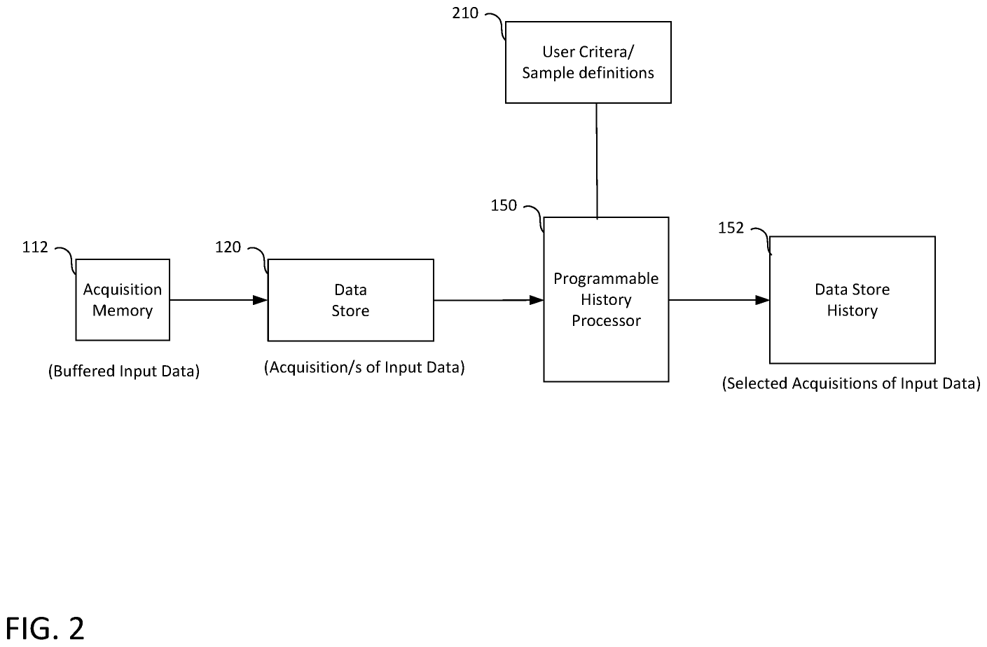

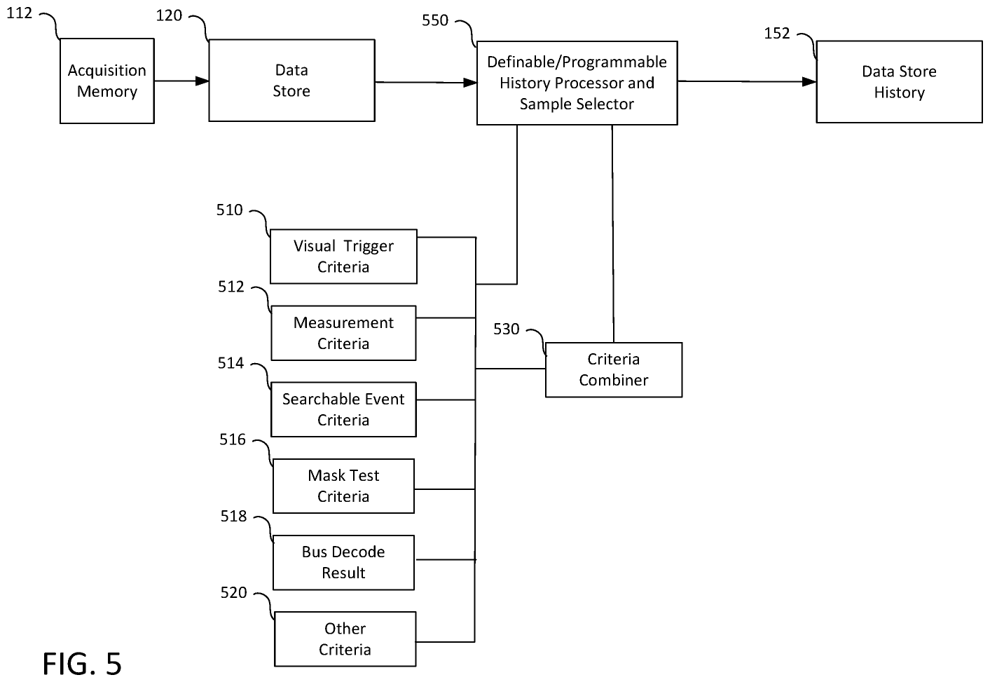

FIG. 2 is a block diagram illustrating high-level functionality of a history processor 150 according to embodiments of the invention. As described above, the instrument 100 gathers input signals from the DUT 101 (FIG. 1) and, when triggered, stores an acquisition in the acquisition memory 112. Next, the acquisition is automatically copied from the acquisition memory 112 to the data store 120. Embodiments of the invention include the programmable history processor 150, which analyzes the acquisition stored in the data store 120 and compares it against user criteria, which may also be called sample definitions 210. Examples of various user criteria 210 are described with reference to FIG. 5 below. In operation, the history processor 150 selects the acquisition from the data store 120 and compares it to the present user criteria 210. When the acquisition matches the present user criteria 210, the acquisition is copied or moved to the data store history 152. In this way, the data store history 152 receives and stores only those acquisitions that match the one or more criteria used by the programmable history processor 150. This enables embodiments of the invention to operate for long periods of time collecting only those acquisitions that are defined by the user criteria 210. It no longer matters that the user criteria specifies an event or occurrence that happens infrequently, because embodiments of the invention may be configured to continuously evaluate each acquisition in the data store 120 for as long as the instrument is in operation. In other words, when a new acquisition is stored in the data store 120, the history processor 150 compares the new acquisition to the user criteria 210. If the acquisition matches the present criteria 210, then the history processor 150 moves or copies that acquisition to the data store history 152, where it will remain indefinitely, until deleted by a user. So, if the present criteria is set to a criteria that occurs an average of only once every four hours, continuously running the instrument 100 will collect in the data store history 152, on average, six matching samples per day. After a week of continuously running the instrument 100, the data store history 152 will contain, on average, forty-two individual acquisitions that were collected from the DUT 101, each of which satisfies the criteria.

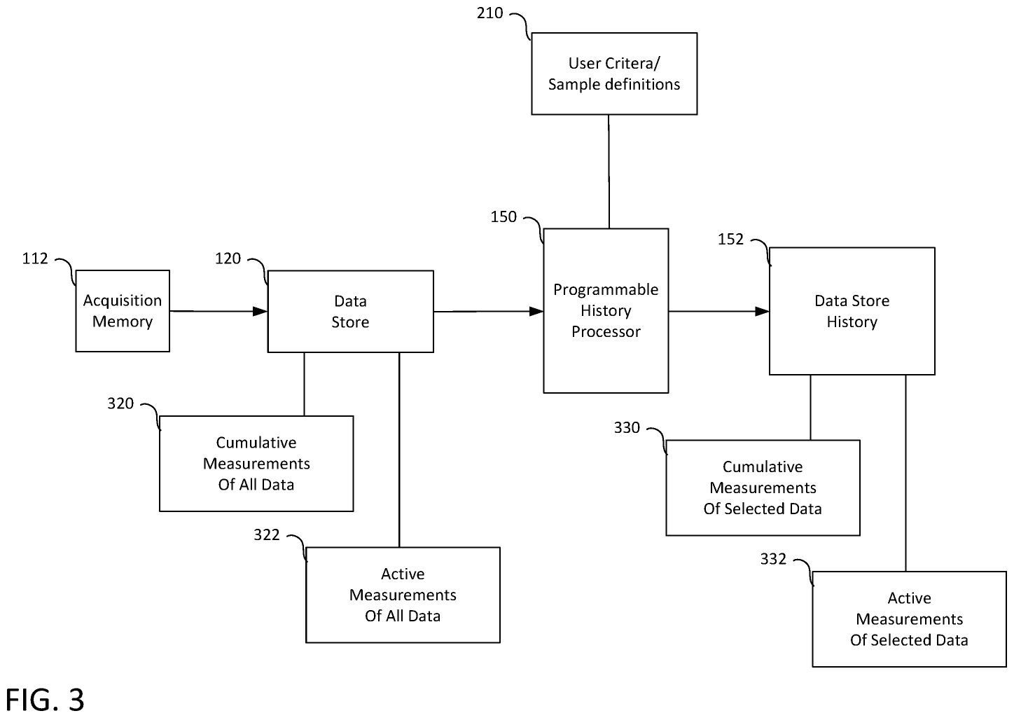

An example of an advantage of including a programmable history processor 150 in an instrument is illustrated in FIG. 3. This figure illustrates how embodiments of the invention enable a user to make measurements on only a defined subset of data that has been acquired by an instrument that includes a programmable history processor. A conventional cumulative measurement operation is illustrated as operation 320. It is a common practice to make cumulative or superlative measurements on data in the data store 120, such as average frequency or maximum voltage. Other examples of accumulated measurements include measurement statistics, histograms, plots, etc., all of which can be produced by the operation 320, which performs such operations on all acquisitions that have been stored in the data store 120. These cumulative measurements may be made and updated by main processor 130 processing an acquisition when it is stored in the data store 120. Operation 320 continues to update cumulative measurements, even though the underlying acquisitions on which the cumulative measurements are based may have been overwritten in the data store 120. Thus, not all of the acquisitions that the operation 320 used to make its cumulative measurements are still available to the user, since most of those acquisitions have been overwritten, and only the last acquisition remains in the data store 120. It is possible that a user wishes to investigate a particular acquisition that was used on the cumulative measurements of operation 320, but that particular acquisition is unavailable because it was overwritten by the operation of the data store 120.

Consider, for example, a user analyzing frequency measurements. Output from the cumulative measurement operation 320 shows a frequency measurement having a maximum of 40.985 MHz and a minimum of 39.263 MHz. The user wishes to investigate the acquisitions that provided both the maximum and minimum frequencies, as they represent the extremes in the acquired dataset used by the cumulative measurement operation 320. But when the user navigates the tools of the instrument to investigate where the maximum and minimum values actually occurred in the dataset, the maximum found in the data store 120 is 40.761 MHz and the minimum found is 39.497 MHz. This is because the acquisitions that contained the cycles of interest happened much earlier and are no longer contained in the data store 120, i.e., those particular acquisitions had been overwritten, although they were used in the cumulative measurements.

Embodiments of the invention, however, may use another operation 330 to perform the same or similar cumulative measurements as those performed by operation 320. The difference is that, whereas the operation 320 performed measurements on acquisitions in the data store 120, which may have been overwritten as the cumulative measurements were being made, the operation 330 performs its cumulative measurements on acquisitions stored in the data store history 152, which are not overwritten. Therefore, all of the acquisitions used to create the cumulative measurements of operation 330 remain in the data store history 152, and are available to the user, should the user wish to investigate particular of those acquisitions used in the cumulative measurements.

Consequently, due to the presence of the programmable history processor 150, embodiments of the disclosure allow the user to select which stored acquisitions are used as a basis for the cumulative measurements. The user may elect to perform cumulative measurements on all previously acquired acquisitions, by using cumulative measurements operation 320. Or, the user may elect to perform cumulative measurements on data stored only in the data store history 152, by using cumulative measurements operation 330. Electing to use the operation 330 causes the instrument 100 to perform cumulative measurements on only the set of acquisitions actually contained in the data store history 152. And, all of the acquisitions used in the cumulative measurements remain available for further inspection in the data store history 152.

Embodiments are not limited to only making cumulative measurements from acquisition data stored in either the data store 120 or data store history 152. But rather embodiments may also perform active analysis and measurements on the data stored in these locations. In addition to the cumulative operations 320, 330, FIG. 3 also illustrates active measurement and analysis operations 322, 332. Active measurement and analysis operation 322 operates on the acquisition stored in the data store 120, while active measurement and analysis operation 332 operates on acquisitions stored in the data store history 150. Active analysis and measurements include measurements of various signal parameters, searches for particular acquisitions or characteristics of stored acquisitions, and bus decodes, etc. But, whereas present instruments are able to perform active analysis and measurements only on data presently stored in the data store 120, which are subject to being overwritten, embodiments according to this disclosure further allow a user to perform active analysis and measurements on data that further meets the criteria provided by the user in criteria 210, which is stored in data store history 152. And further, as described above, the acquisitions stored in the data store history 152 are not subject to being overwritten, or deleted without express direction from the user.

As described above, acquisitions stored in the data store history 152 include only those acquisitions that satisfied the user criteria 210 specified to the programmable history processor 150. So, embodiments of the disclosure provide the user with an ability to perform specific active or cumulative measurements on particularly qualified data, i.e., data from the data store 120 that meets the user specified criteria 210, and therefore has been stored in the data store history 152.

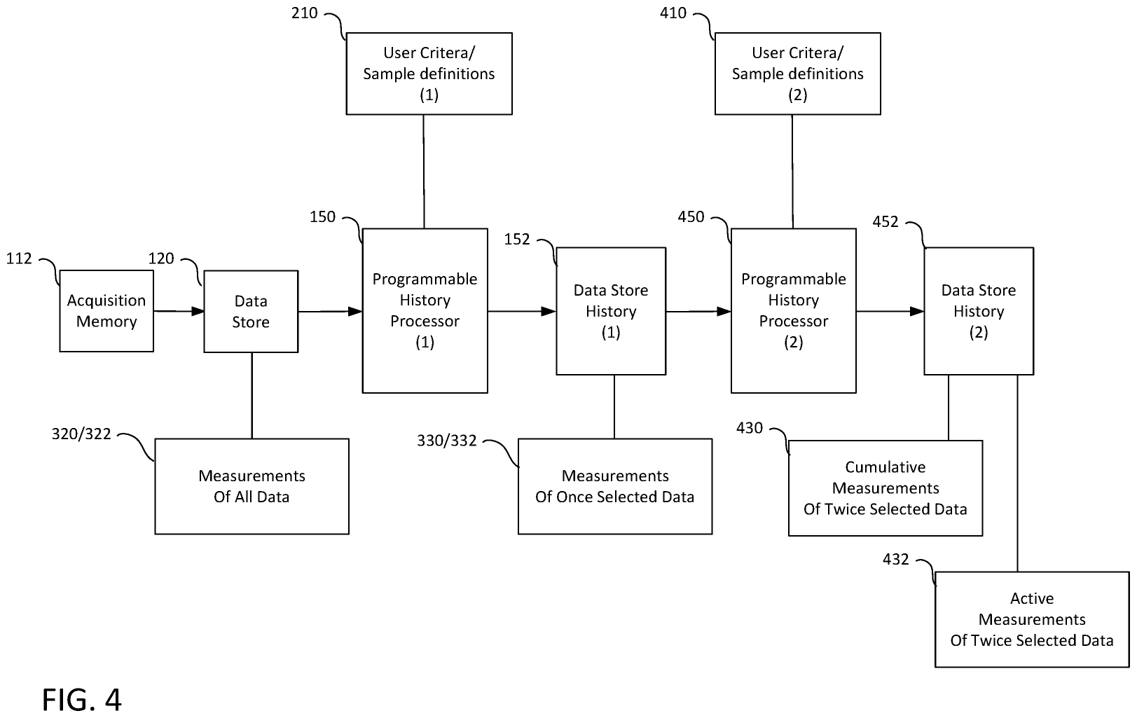

This concept of refining datasets according to criteria may be extended, as illustrated in FIG. 4, which includes the same functions and operations of FIG. 3, but adds a second set of user criteria 410, which is used to drive a second programmable history processor 450. In practice, of course, the history processor 150 itself may use the second set of criteria 410 instead of a second programmable history processor 450, but FIG. 4 illustrates a second instance of a history processor for ease of illustration. The second programmable history processor 450 applies the second user-specified criteria 410 to the acquisitions that were already stored in the data store history 152, i.e., to acquisitions that had already been qualified or selected once. Then, those sample acquisitions that satisfy the second set of criteria 410, and had also previously satisfied the first set of criteria 210, are stored in a second data store history 452. A cumulative measurement operation or process 430 is configured to perform cumulative measurements on only the data stored in the second data store history 452, and an active analysis and measurement operation or process 432 is also configured to perform active analysis and measurements on only the data stored in the second data store history 452. This process of applying new user criteria to already-selected or qualified acquisitions may be repeated multiple times, to further qualify data using additional user criteria to narrow the set of selected or qualified data for the second data store history 452. Although FIG. 4 illustrates one way of implementing a system that performs measurements on only multiply-qualified or multiply-selected data, other embodiments may use different configurations, of course. For example, it is not necessary to have a second data store history 452 to store the multiply-qualified data, but rather those acquisitions could be identified with a data or metadata tag, and remain in the data store history 152 or elsewhere in the instrument 100 or elsewhere.

FIG. 5 is a block diagram illustrating how a user may specify various criteria when configuring a programmable history processor 550, according to embodiments of the invention. The illustrated programmable history processor 550 may be an example of any of the programmable history processors 150, 450, described above.

As illustrated in FIG. 5, the programmable history processor 550 may accept various forms of user criteria to be applied to the acquisition stored in the data store 120 to qualify or select the acquisitions to be identified and/or moved to the data store history 152. Further, an operation or process 530 may be used to combine multiple criteria or criteria of multiple types to be supplied to the programmable history processor 550, as described below.

The user criteria applied by the programmable history processor 550 may be any type of criteria able to be specified by a user of the instrument, such as the instrument 100 of FIG. 1. For instance, user criteria may include one or more of visual trigger criteria 510, which is a trigger that identifies waveform events by graphically comparing waveform outputs to one or more graphical shapes or windows. Waveform events, or the acquisitions that include waveforms that meet the graphical definition are included in the set identified by the visual trigger, while those that do not meet the graphical definition are not included. Another criteria that may be used by the programmable history processor is a measurement criteria 512, such as whether a data sample of an acquisition exceeds a certain voltage or has a frequency above or below a certain threshold. For example, the user may specify that the programmable history processor 550 store only those acquisitions that contain at least one positive pulse width on Channel 1 that is greater than 100 ms. Another criteria that may be used by the programmable history processor is a searchable event criteria 514. This type of criteria is based on types of events around a waveform sample, such as a timeout, where no valid signal is received for a period of time, or time between events, such as time between two signal edges. Other searchable event criteria 514 may include storing only an acquisition if a defined search generates more than 25 rise time measurements that are all faster than a user defined duration. Other types of searchable event triggers are well known. Another criteria that may be used by the programmable history processor is a communication or mask test criteria 516, which compares a waveform against an industry standard mask template. Another criteria that may be used by the programmable history processor is a bus decode result criteria 518. For example, the user may specify that only acquisitions that are written to a particular bus address, such as x86h, are stored in the data store history 152. Finally, other criteria 520 indicates that there are many other types of triggers or criteria that are available to be used by a user of an instrument, and known to those having skill in the art. Examples of other criteria 520 could include any hardware-based acquisition type, such as Edge, Pulse Width, Glitch, Runt, Window, Logic, Bus, Timeout, Transition time, Memory system triggering, Protocol triggering, Pattern triggering, Serial lane violation, and Beacon width violation, etc. Further, many of the criteria 510-518 may be made in the frequency domain, rather than in the time domain, as described above. None of the criteria 510-520 is limited to any particular criteria, but instead includes any criteria that is able to be specified by the user. Embodiments of the invention may use any or all of these criteria in conjunction with the programmable history processor.

As depicted in FIG. 5, any of these criteria 510-520 may be specified by the user and provided to the programmable history processor 550 to apply against data acquisitions stored in the instrument. Acquisitions that conform or match the criteria is identified and may be moved to the data store history 152. In this way, the programmable history processor 550 operates as a filter, or selector, to filter or select particular of the stored data acquisitions for further processing or analysis, as described above.

Further, a criteria combiner 530 provides the user with an ability to customize, with almost unlimited possibilities, multiple of any of the criteria 510-520 identified above. The criteria combiner 530 may be a Boolean operator, and allow AND, NAND, OR, or NOR combinations, as well as the NOT function. For example, a user may specify that the criteria used by the programmable history processor 550 is when a certain visual trigger 510 is satisfied, or TRUE, but only when a searchable event criteria 514 is also TRUE, such as the particular acquisition being later than the 1000^{th} acquisition since the instrument began receiving acquisitions from the DUT. The criteria combiner 530 is not limited to a single criteria from each class or type of criteria 510-520, but may include multiple instances. For example, the user could use measurement criteria 512 to specify as criteria only those acquisitions that included samples having a minimum voltage of 1.80 volts and a frequency over 1.51 MHz. Or the criteria could be set to select only those acquisitions that fell outside a first visual trigger criterion 510 while simultaneously being not inside a second visual trigger criterion.

In addition to the Boolean functions described above, the criteria combiner 530 may support nested logic, which may be specified with parenthesis, brackets, or any other symbol. For example, a particular combined criteria may take the form of CO:[(within Visual Trigger 1 AND acquisition number>100) OR (within Visual Trigger 2 AND acquisition number>2000)].

One advantage to the flexibility of the criteria combiner 530 is that it can be used to specify a multitude of different acquisition data that is of interest to the user. For example, the user may specify the criteria used by the programmable history processor 550 is any acquisition having the criteria C1:[falls within Visual Trigger 1 OR has a voltage over 1.63 volts OR has frequency less than 1.5 MHz OR matches Mask 1]. This set of criteria C1 may capture a large number of acquisitions into the data store history 152 based on the large number of OR clauses in the criteria C1. But, recall from the description of FIG. 4 above that the programmable history processor 550 may be run multiple times, each having a different criteria. So, acquisitions from the data store 120 evaluated by the programmable history processor 550 may include a large number of samples that may be interesting for various reasons and stored in the data store history 152. Then, as illustrated in FIG. 4, a second set of criteria may be run against the data from the data store history 152. For example, this second set of criteria may specify that only those samples that have a voltage over 1.63 volts and under 1.66 volts are selected and stored in the second data store history 452 (C2: [(voltage>1.63 volts) AND (voltage<1.66 volts)]. This second criteria C2 may include only a small number of acquisitions. A third set of criteria C3 may be applied to any of the acquisitions stored in the instrument 100. That is, a third set of criteria C3 may be used by a programmable history processor to evaluate the acquisition stored in the main data store 120, which includes all of the last N samples, acquisitions stored in the data store history 152, which includes those acquisitions that satisfy the C1 criteria, or acquisitions from the data store history 452, which includes those acquisitions that satisfy both the C1 and the C2 criteria. The ability of the criteria combiner 530 to combine multiple, disparate criteria from any possible source, or metric, of the instrument 100, with Boolean and nested operators, paired with the ability to execute the selection process made by the programmable history processor multiple times, on different data sets, and the ability to use different sets of criteria, provides the user a tremendous ability to quickly find acquisitions of interest, which has never before been available.

Aspects of the disclosure may operate on particularly created hardware, firmware, digital signal processors, or on a specially programmed computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a computer readable storage medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or computer-readable storage media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the technologies disclosed herein are provided below. An embodiment of the technologies may include any one or more, and any combination of, the examples described below.

Example 1 is a test and measurement device, including an input configured to receive a signal for testing, an acquisition processor configured to generate an acquisition from the received signal, store the acquisition in an acquisition memory, and copy the acquisition to a data store, and an acquisition evaluator configured to compare the acquisition in the data store against one or more criteria, and identify whether the selected acquisition meets the one or more criteria.

Example 2 is a test and measurement device according to Example 1, in which the acquisition evaluator is structured to copy the acquisition to a secondary memory when the acquisition meets the one or more criteria.

Example 3 is a test and measurement device according to any of the preceding examples, in which the one or more criteria includes at least two criteria joined by a Boolean operator.

Example 4 is a test and measurement device according to any of the preceding Examples 2 and 3, in which the acquisition evaluator is further configured to select an acquisition from the secondary memory, compare the selected acquisition from the secondary memory to a second one or more criteria, and identify whether the selected acquisition from the secondary memory meets the second one or more criteria.

Example 5 is a test and measurement device according to any of the preceding Examples 2-4, further comprising a measurement processor configured to make a measurement from one or more acquisitions stored in the secondary memory.

Example 6 is a test and measurement device according to Example 5, in which the measurement processor is a cumulative processor.

Example 7 is a test and measurement device according to any of the preceding Examples, in which the one or more criteria comprises at least one of a visual trigger, a measurement trigger, an event trigger, a search result, a mask test, a bus decode result, or a hardware trigger.

Example 8 is a method in a test and measurement instrument, including receiving a test signal at a test input, producing digitized samples of the signal under test as an acquisition and storing the acquisition in an acquisition memory, copying the acquisition from the acquisition memory to a memory store of the instrument, comparing the acquisition in the data store to one or more criteria, and identifying whether the acquisition meets the one or more criteria.

Example 9 is a method in a test and measurement instrument according to Example 8, further comprising copying the acquisition to a secondary memory store when the acquisition meets the one or more criteria.

Example 10 is a method in a test and measurement instrument according to any preceding Example methods, in which the one or more criteria includes at least two criteria joined by a Boolean operator.

Example 11 is a method in a test and measurement instrument according to Examples 9-10, further comprising selecting an acquisition from the secondary memory, comparing the selected acquisition from the secondary memory to a second one or more criteria, and identifying whether the selected acquisition from the secondary memory meets the second one or more criteria.

Example 12 is a method in a test and measurement instrument according to any of the preceding Example methods, further comprising making a measurement from one or more acquisitions stored in the secondary memory.

Example 13 is a method in a test and measurement instrument according to Example 12, in which making a measurement from one or more acquisitions stored in the secondary memory comprises making a cumulative measurement.

Example 14 is a method in a test and measurement instrument according to any of the preceding Example methods, in which comparing a selected one of the plurality of acquisitions to one or more criteria comprises comparing a selected one of the plurality of acquisitions to at least one of a visual trigger, a measurement trigger, an event trigger, a search result, a mask test, a bus decode result, or a hardware trigger.

The previously described versions of the disclosed subject matter have many advantages that were either described or would be apparent to a person of ordinary skill. Even so, these advantages or features are not required in all versions of the disclosed apparatus, systems, or methods.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

Although specific examples of the invention have been illustrated and described for purposes of illustration, it will be understood that various modifications may be made without departing from the spirit and scope of the invention. Accordingly, the invention should not be limited except as by the appended claims.

1. A test and measurement device, comprising:
an input configured to receive a signal for testing;
an acquisition processor configured to generate an acquisition from the received signal, store the acquisition in an acquisition memory, and copy the acquisition to a data store; and
an acquisition evaluator configured to:
compare the acquisition in the data store against one or more criteria, and
identify whether the selected acquisition meets the one or more criteria.

2. The test and measurement device according to claim 1 in which the acquisition evaluator is structured to copy the acquisition to a secondary memory when the acquisition meets the one or more criteria.

3. The test and measurement device according to claim 1 in which the one or more criteria includes at least two criteria joined by a Boolean operator.

4. The test and measurement device according to claim 2 in which the acquisition evaluator is further configured to:
select an acquisition from the secondary memory;
compare the selected acquisition from the secondary memory to a second one or more criteria; and
identify whether the selected acquisition from the secondary memory meets the second one or more criteria.

5. The test and measurement device according to claim 2, further comprising a measurement processor configured to make a measurement from one or more acquisitions stored in the secondary memory.

6. The test and measurement device according to claim 5, in which the measurement processor is a cumulative processor.

7. The test and measurement device according to claim 1 in which the one or more criteria comprises at least one of a visual trigger, a measurement trigger, an event trigger, a search result, a mask test, a bus decode result, or a hardware trigger.

8. A method in a test and measurement instrument, the method comprising:
receiving a test signal at a test input;
producing digitized samples of the signal under test as an acquisition and storing the acquisition in an acquisition memory;
copying the acquisition from the acquisition memory to a memory store of the instrument;
comparing the acquisition in the data store to one or more criteria; and
identifying whether the acquisition meets the one or more criteria.

9. The method according to claim 8, further comprising copying the acquisition to a secondary memory store when the acquisition meets the one or more criteria.

10. The method according to claim 8 in which the one or more criteria includes at least two criteria joined by a Boolean operator.

11. The method according to claim 9, further comprising:
selecting an acquisition from the secondary memory;
comparing the selected acquisition from the secondary memory to a second one or more criteria; and
identifying whether the selected acquisition from the secondary memory meets the second one or more criteria.

12. The method according to claim 9, further comprising making a measurement from one or more acquisitions stored in the secondary memory.

13. The method according to claim 12, in which making a measurement from one or more acquisitions stored in the secondary memory comprises making a cumulative measurement.

14. The method according to claim 8 in which comparing a selected one of the plurality of acquisitions to one or more criteria comprises comparing a selected one of the plurality of acquisitions to at least one of a visual trigger, a measurement trigger, an event trigger, a search result, a mask test, a bus decode result, or a hardware trigger.
